(19) United States
(12) Patent Application Publication
(10) Pub. No.: US 2013/0025672 A1
(43) Pub. Date: Jan. 31, 2013

(54) GLASS SUBSTRATE COATED WITH LAYERS HAVING IMPROVED MECHANICAL STRENGTH

(71) Applicants: Stéphane Auvray, Suresnes (FR); Clément Briquet, Elincourt Sainte Marguerite (FR); Bertrand Kuhn, Paris (FR)

(72) Inventors: Stéphane Auvray, Suresnes (FR); Clément Briquet, Elincourt Sainte Marguerite (FR); Bertrand Kuhn, Paris (FR)

(73) Assignee: SAINT-GOBAIN GLASS FRANCE, Courbevoie (FR)

(21) Appl. No.: 13/580,319

(22) PCT Filed: Feb. 4, 2011
(86) PCT No.: PCT/FR11/50226

§ 371 Date: Oct. 4, 2012

(30) Foreign Application Priority Data
Feb. 22, 2010 (FR) 1051244

(51) Int. Cl. H01L 31/0224; H01J 17/04; B05D 1/36; B32B 17/06; B05D 5/12

(52) U.S. Cl. 136/256; 428/432; 428/428; 428/336; 428/216; 427/109; 313/631

(57) ABSTRACT

A transparent glass substrate, associated with a transparent electrically conductive layer capable of constituting an electrode of a photovoltaic module, and composed of a doped oxide, characterized by the interposition, between the glass substrate and the transparent electrically conductive layer, of a layer of one or more first nitride(s) or oxynitride(s), or oxide(s) or oxycarbide(s) having good adhesive properties with the glass, then of a mixed layer of one or more second nitride(s) or oxynitride(s), or oxide(s) or oxycarbide(s) having good adhesive properties with the glass, and of one or more third nitride(s) or oxynitride(s), or oxide(s) or oxycarbide(s) capable of constituting, optionally in the doped state, a transparent electrically conductive layer.

The invention relates to a front face substrate of a photovoltaic module, in particular a transparent glass substrate, and also to a photovoltaic module incorporating such a substrate.

In a photovoltaic module, a photovoltaic system containing photovoltaic material which produces electrical energy under the effect of incident radiation is positioned between a back face substrate and a front face substrate, this front face substrate being the first substrate that is passed through by the incident radiation before it reaches the photovoltaic material.

Photovoltaic materials are understood to mean absorber agents which may be composed, for example, of cadmium telluride, amorphous silicon, microcrystalline silicon or ternary chalcopyrites which generally contain copper, indium and selenium. Layers of such absorbent agent are referred to as CISe₂ layers. The layer of absorber agent may also contain gallium (e.g. Cu(In,Ga)Se₂ or CuGaSe₂), aluminum (e.g. Cu(In,Al)Se₂) or sulfur (e.g. CuIn(Se,S)). They are denoted in general by the term chalcopyrite absorber agent layers.

In the photovoltaic cell, the front face substrate usually comprises, beneath a main surface turned toward the photovoltaic material, a transparent electrode coating in electrical contact with the photovoltaic material placed beneath when the main direction of arrival of the incident radiation is considered to be via the top.

Within the context of the present invention, the term “photovoltaic cell” should be understood to mean any assembly of constituents that produces an electrical current between its electrodes by solar radiation conversion, whatever the dimensions of this assembly and whatever the voltage and the intensity of the current produced, and in particular whether or not this assembly of constituents has one or more internal electrical connections (in series and/or in parallel). The notion of a “photovoltaic cell” within the context of the present invention is therefore equivalent here to that of a “photovoltaic module” or else a “photovoltaic panel”.

The present invention relates to the transparent conductive layers, in particular based on oxides, of great advantage on a glass substrate.

Examples thereof are ITO (indium tin oxide) layers of indium oxide doped with tin, SnO₂:F layers of tin oxide doped with fluorine. Such layers constitute electrodes in certain applications: flat lamps, electroluminescent glazing, electrochromic glazing, liquid crystal display screen, plasma screen, photovoltaic panel or module, electrically heated glass. In other applications for low-emissivity glazing, for example, these transparent conductive layers do not have to be put under voltage.

In the prior art, these transparent conductive layers are in general associated with a sublayer in order to improve the optical properties of a transparent conductive layer or of a stack of transparent conductive layers on a glass substrate. Without being exhaustive, mention may especially be made of EP 611 733 by PPG which proposes a mixed, gradient layer of silicon oxide and of tin oxide in order to prevent the iridescence effects induced by the transparent conductive layer of fluorine-doped tin oxide. The patent by Roy Gordon, FR 2 419 335, also proposes a variant of this sublayer for improving the color properties of a transparent conductive layer of fluorine-doped tin oxide. The precursors cited in this patent are on the other hand unusable on an industrial scale. Mention may also be made of the patent EP 0 275 662 B1 by Pilkington which proposes a sublayer composed of silicon oxycarbide beneath an electrically conductive layer based on fluorine-doped tin oxide, said sublayer providing the double role of barrier layer against the diffusion of alkali metals from the glass and also of anti-iridescence layer for neutralizing the color in reflection. SAINT-GOBAIN also possesses know-how in this field: patent FR 2 736 632 thus proposes a mixed, inverse index-gradient sublayer of silicon oxide and of tin oxide as an anti-color sublayer for a transparent conductive layer of fluorine-doped tin oxide.

On the other hand, it has been observed that there is a tendency for transparent conductive oxide layers on glass to delaminate in the photovoltaic modules or all the active applications mentioned previously. Delamination of the layer is understood to mean its loss of adhesion to the glass. This is seen by the formation of cracks that can be easily detected by a person skilled in the art. Crack propagation may lead to detachment of the layer thus eliminating the functionality of the application.

An aging test has been developed in order to accelerate the bringing to light of this phenomenon. It consists in subjecting the glass and its electrode, for variable times, to the action of electric fields. The objective of this test is to force the diffusion of alkali metals from the glass toward the layer, the latter being one of the causes responsible for the appearance of the delamination. The delamination test is carried out in the following manner. Firstly, a counterelectrode for example based on silver is deposited on the glass, on the face opposite the side provided with the electrically conductive electrode. Secondly, the assembly thus formed is brought to 200° C. either by direct contact of the silver-based face on a hotplate or by means of annealing in an oven. Once thermal equilibrium is obtained, a potential of around −200 V is applied to the electrically conductive electrode, the silver-based counterelectrode being grounded. This results in the formation of an electric field which induces the migration of the alkali metals from the glass to the electrically conductive layer. This test is carried out for variable times ranging from one minute to about twenty minutes so as to lead to a charge displacement of 0.1 to 40 mC/cm² or more, for example, depending on the electrical resistivity values of the glass under standard temperature and pressure conditions. A floor value of these displaced electrical charges is observed, starting from which delamination occurs. This delamination is also observed with the sublayers mentioned in the prior art.

In order to solve the problems of delamination of transparent conductive oxide layers deposited on a glass substrate, the inventors have developed a stack of sublayers joining a glass substrate to a transparent conductive oxide layer that considerably improves the adhesion of the latter, especially under conditions where the assembly is placed under an electric field and at relatively high temperatures, greater than 100° C. or even 200° C.

One subject of the invention is therefore a transparent glass substrate, associated with a transparent electrically conductive layer capable of constituting an electrode of a photovoltaic module, and composed of a doped oxide, characterized by the interposition, between the glass substrate and the transparent electrically conductive layer, of a layer of one or more first nitride(s) or oxynitride(s), or oxide(s) or oxycarbide(s) having good adhesive properties with the glass, then of a mixed layer of one or more second nitride(s) or oxynitride(s), or oxide(s) or oxycarbide(s) having good adhesive properties with the glass, and of one or more third nitride(s) or oxynitride(s), or oxide(s) or oxycarbide(s) capable of constituting, optionally in the doped state, a transparent electrically conductive layer.

Thus, the invention makes it possible to obtain stacks of layers suitable, in several respects, for photovoltaic modules.

The mechanical strength on the glass substrate is not adversely affected in the presence of an electric field, the origin of which may be internal or external linked to the application of voltage to the photovoltaic module or to the presence of a metal frame around the module, the potential of which may be fluctuating, for use under actual outdoor sun exposure conditions. The solar spectrum to which reference is made here is the AM 1.5 solar spectrum as defined by the ASTM standard. This considerable improvement may be obtained for large glass surfaces (full-width float, in French PLF), since deposition processes compatible with such dimensions are available for the layers in question.

Furthermore, esthetic defects such as a local variation of the diffuse transmission and of the haze, measured using a haze meter, may be solved, so that the invention is very particularly well suited to the manufacture of photovoltaic modules.

Advantageously, the mechanical strength of the substrate of the invention is not adversely affected in the 24 hours following a treatment by an electric field of at least 100 V, preferably 200 V on either side of the substrate, and a temperature of at least 200° C., inducing an electrical charge displacement of at least 2 mC/cm², preferably 4 mC/cm² depending on the electrical resistivity values of the glass substrate at the test temperature. The mechanical strength is understood to mean that the stack or a portion of the stack does not delaminate.

Preferably,
said first and second nitride(s) or oxynitride(s), or oxide(s) or oxycarbide(s) are chosen from the nitrides or oxynitrides, or oxides or oxycarbides of Si, Al and Ti, in particular SiOC, SiO₂, SiON, TiO₂, TiN and Al₂O₃;
said third nitride(s) or oxynitride(s), or oxide(s) or oxycarbide(s) are chosen from the nitrides or oxynitrides, or oxides or oxycarbides of Sn, Zn and In, in particular SnO₂, ZnO and InO;
said transparent electrically conductive layer is composed of a doped oxide of Sn, Zn or In, such as SnO₂:F, SnO₂:Sb, ZnO:Al, ZnO:Ga, ZnO:B, InO:Sn or ZnO:In.

In accordance with embodiments that provide an optimal combination of the mechanical strength and of the desired optical properties of the substrate,
said layer of one or more first nitride(s) or oxynitride(s), or oxide(s) or oxycarbide(s) is a layer of silicon oxycarbide SiOC;
said mixed layer is a layer of silicon tin oxide;
the [Si]/[Sn] molar ratio in said mixed layer is at least equal to 1, preferably to 2; the inventors have noticed that this feature has a very particular positive effect on the mechanical strength as defined above, in the context of use as a photovoltaic module in particular;
the thickness of said layer of one or more first nitride(s) or oxynitride(s), or oxide(s) or oxycarbide(s) is at least equal to 5 nm;
the thickness of said layer of one or more first nitride(s) or oxynitride(s), or oxide(s) or oxycarbide(s) is at most equal to 80 nm; indeed, greater thicknesses do not provide further advantage from the point of view of the mechanical strength for example;
the thickness of said mixed layer is at least equal to 3 nm;
the thickness of said mixed layer is at most equal to 65 nm, preferably 40 nm; for greater thicknesses local variations of the haze may appear that adversely affect, to a greater or lesser extent, the esthetic appearance of the final products, especially of the photovoltaic modules;
said transparent electrically conductive layer composed of a doped oxide is joined to said mixed layer with interposition of a layer of the same undoped oxide, the combined thickness of the two layers of undoped oxide and of doped oxide being in particular between 300 and 1600 nm, preferably at most equal to 1100 nm and particularly preferably to 900 nm, and the ratio of the thicknesses of the two layers then being, between 1:4 and 4:1.

Another subject of the invention is a process for manufacturing a substrate as described above, for which said layer of one or more first nitride(s) or oxynitride(s), or oxide(s) or oxycarbide(s), said mixed layer then said transparent electrically conductive layer are obtained by successive chemical vapor depositions.

Chemical vapor deposition (CVD) can be easily carried out on an industrial scale on large glass surfaces, in particular on full-width float (in French, PLF). No vacuum installation is required.

Mention is made of the following:
as precursor of SiO₂ (SiOC—SiOSn): tetraethoxysilane (TEOS), hexamethyldisiloxane (HMDSO), silane (SiH₄);
as precursor of SnO₂ (SiOSn, SnO₂, SnO₂:F): monobutyltin trichloride (MBTCl), dibutyltin diacetate (DBTA), tin tetrachloride (SnCl₄); dibutyltin dichloride (DBTCl);
as other carbon-based precursor (SiOC): ethylene, carbon dioxide;
as other oxygen-based precursor (SiOC, SiOSn, SnO₂, SnO₂:F): carbon dioxide, oxygen, water;
as fluorine-based precursor (SnO₂:F): tetrafluoromethane (CF₄), octafluoropropane (C₃F₈), hexafluoroethane (C₂F₆), hydrogen fluoride (HF), difluorochloromethane (CHClF₂), difluorochloroethane (CH₃CClF₂), trifluoromethane (CHF₃), dichlorodifluoromethane (CF₂Cl₂), trifluorochloromethane (CF₃Cl), trifluorobromomethane (CF₃Br), trifluoroacetic acid (TFA, CF₃COOH), nitrogen trifluoride (NF₃).

Said successive depositions are advantageously carried out at a temperature of the substrate at least equal to 500° C., which may reach values of 650° C. or more.

For example, the SiOC layer may be deposited on the glass substrate production line and the SiOSn layer outside of this production line, or alternatively both these layers may be deposited outside of this production line.

However, according to one preferred embodiment of the process, said successive chemical vapor depositions are carried out on the glass substrate production line, for example on a continuous ribbon in the section comprising the float, the exit and the start of the lehr.

Other subjects of the invention are moreover:
a photovoltaic module comprising a substrate described above;
a shaped electrically heated glass comprising a substrate as described previously;
a plasma screen (PDP for plasma display panel) comprising a substrate according to the invention;
a flat lamp electrode comprising such a substrate; and
a low-emissivity (low-e) glass comprising such a substrate.

The invention is illustrated by the following examples.

### COMPARATIVE EXAMPLE 1

In all the examples that follow, layers are deposited on 5 cm×5 cm×3.2 mm samples of soda-lime float glass by chemical vapor deposition. The samples are heated at 600° C.

The proportions indicated in the remainder of the examples are molar percentages.

A 25 nm layer of SiOC is deposited here starting from:
7.8% of SiH₄;
26.6% of C₂H₄;
47.8% of N₂; and
17.7% of CO₂.

Next, a 1 μm layer of SnO₂:F is deposited starting from:
3.63% of mono-n-butyltin trichloride (MBTCl);
0.45% of trifluoroacetic acid (TFA);
20% of water;
57% of N₂; and
19% of O₂.

In all the examples, the sample is subjected to an electrical voltage of 200 V on either side of the sample and also to a temperature of 200° C. for variable times. The floor value of displaced electrical charges for which there is delamination is observed, 24 h after this operation (see above detailed description of this aging test).

This floor value is here less than 0.5 mC/cm², which is considered to correspond to a relatively low mechanical strength, insufficient for many applications, in particular as a photovoltaic module.

Furthermore, substantial local variation of the haze was not observed.

### COMPARATIVE EXAMPLE 2

A 40 nm layer of SiOSn is deposited starting from:
0.08% of MBTCl;
0.04% of tetraethoxysilane (TEOS);
0.17% of water;
93.1% of N₂; and
6.6% of O₂.

The Si/Sn molar ratio in this layer is 0.5.

Next, a 1 μm layer of SnO₂:F is deposited as in Example 1.

A delamination is observed starting from a value of displaced electrical charges of less than 0.5 mC/cm², which is insufficient.

This sample moreover exhibited local variations of the haze adversely affecting the esthetic appearance of the product.

### EXAMPLE 3

The following are deposited:
a 25 nm layer of SiOC as in Example 1;

a 40 nm layer of SiOSn as in Example 2 (Si/Sn molar ratio of 0.5); and
a 1 mm layer of SnO₂:F as in the preceding examples.

A delamination is observed starting from a value of displaced electrical charges of less than 1 mC/cm², which is substantially improved relative to those of the preceding examples, but which may still be insufficient in certain intended applications.

No local variation of the haze was observed.

### EXAMPLE 4

The following are deposited:
a 25 nm layer of SiOC as in Example 3;
a 40 nm layer of SiOSn having an Si/Sn molar ratio of 1.4 starting from:
   0.08% of MBTCl;
   0.11% of TEOS;
   0.17% of water;
   93% of N₂; and
   6.6% of O₂; and
a layer of SnO₂:F as in Example 3.

A delamination occurs starting from a value of displaced electrical charges of 4-5 mC/cm², which is adequate for many intended applications.

No local variation of the haze was observed.

### EXAMPLE 5

Example 4 is reproduced, modifying only the SiOSn layer, which here has an Si/Sn molar ratio of 2.7, and is obtained from:
0.08% of MBTCl;
0.23% of TEOS;
0.17% of water;
92.9% of N₂; and
6.6% of O₂.

A delamination occurs starting from a floor value of displaced electrical charges of 10 mC/cm², which is very good.

No local variation of the haze was observed.

### EXAMPLE 6

Examples 3 to 5 are reproduced, by modifying the SiOSn layer, having a thickness of 80 nm and having an Si/Sn molar ratio of 2.7, which layer is obtained from:
0.14% of MBTCl;
0.37% of TEOS;
0.26% of water;
86.8% of N₂; and
12.4% of O₂.

A delamination occurs starting from a value of displaced charges of 15 mC/cm², which is very good.

However, local variations of the haze were observed.

### EXAMPLE 7

Example 6 is reproduced, but with a value of 0.5 for the Si/Sn molar ratio of the SiOSn layer, obtained from:
0.14% of MBTCl;
0.07% of TEOS;
0.26% of water;
87.1% of N₂; and
12.4% of O₂.

A delamination occurs starting from a value of displaced charges of less than 1 mC/cm², which may or may not be suitable depending on the applications, but which is relatively low.

Local variations of the haze are observed. One interpretation could render the relatively large thickness of the SiOSn layer (80 nm), as in Example 6, responsible therefor.

### EXAMPLE 8

The following are deposited:
a 50 nm layer of SiOC from:
   10.2% of SiH₄;
   35% of C₂H₄;
   31.5% of N₂; and
   23.3% of CO₂;
a 20 nm layer of SiOSn having an Si/Sn molar ratio of 0.6, obtained from:
   0.04% of MBTCl;
0.02% of TEOS;
   0.11% of water;
   96.2% of N₂; and
3.6% of O₂; and
the same SnO₂:F layer as in the preceding examples.

A delamination occurs starting from a value of displaced electrical charges of less than 2 mC/cm², which may be sufficient in certain applications, but can nevertheless be improved.

No local variation of the haze was observed.

### EXAMPLE 9

Example 8 is reproduced, modifying only the SiOSn layer, this time having a thickness of 50 nm and an Si/Sn molar ratio of 2.7, obtained from:
0.10% of MBTCl;
0.27% of TEOS;
0.22% of water;
91.3% of N₂; and
8.1% of O₂.

The floor value of displaced charges at which a delamination is experienced is high here, at 12 mC/cm².

No local variation of the haze was observed.

### EXAMPLE 10

Examples 8 and 9 are reproduced, modifying only the SiOSn layer, here having a thickness of 70 nm and an Si/Sn molar ratio of 2.7, which layer is obtained from:
0.13% of MBTCl;
0.37% of TEOS;
0.31% of water;
88.1% of N₂; and
11.1% of O₂.

The floor value of displaced charges starting from which a delamination is observed is here the highest: 20 mC/cm².

However, the esthetic appearance has been slightly adversely affected by local variations of the haze attributed to the relatively large thickness of the SiOSn layer.

Thus the invention has made available a stack of layers that provides a high mechanical strength and high adjustable optical properties, perfectly suited to demanding applications, especially for photovoltaic modules. This stack is of course compatible with obtaining the functionality of a photovoltaic module at the highest degree expected at the present time.

1. A transparent glass substrate, associated with a transparent electrically conductive layer capable of constituting an electrode of a photovoltaic module, and composed of a doped oxide, wherein, between the glass substrate and the transparent electrically conductive layer, of a layer of one or more first nitride(s) or oxynitride(s), or oxide(s) or oxycarbide(s) having good adhesive properties with the glass, and then of a mixed layer of one or more second nitride(s) or oxynitride(s), or oxide(s) or oxycarbide(s) having good adhesive properties with the glass, and of one or more third nitride(s) or oxynitride(s), or oxide(s) or oxycarbide(s) capable of constituting, optionally in the doped state, a transparent electrically conductive layer, are interposed.

2. The substrate as claimed in claim 1, wherein said first and second nitride(s) or oxynitride(s), or oxide(s) or oxycarbide(s) are chosen from the nitrides or oxynitrides, or oxides or oxycarbides of Si, Al and Ti.

3. The substrate as claimed in claim 1, wherein said third nitride(s) or oxynitride(s), or oxide(s) or oxycarbide(s) are chosen from the nitrides or oxynitrides, or oxides or oxycarbides of Sn, Zn and In.

4. The substrate as claimed in claim 1, wherein said transparent electrically conductive layer is composed of a doped oxide of Sn, Zn or In.

5. The substrate as claimed in claim 1, wherein said layer of one or more first nitride(s) or oxynitride(s), or oxide(s) or oxycarbide(s) is a layer of silicon oxycarbide SiOC.

6. The substrate as claimed in claim 1, wherein said mixed layer is a layer of silicon tin oxide.

7. The substrate as claimed in claim 6, wherein a [Si]/[Sn] molar ratio in said mixed layer is at least equal to 1.

8. The substrate as claimed in claim 1, wherein a thickness of said layer of one or more first nitride(s) or oxynitride(s), or oxide(s) or oxycarbide(s) is at least equal to 5 nm.

9. The substrate as claimed in claim 1, wherein a thickness of said layer of one or more first nitride(s) or oxynitride(s), or oxide(s) or oxycarbide(s) is at most equal to 80 nm.

10. The substrate as claimed in claim 1, wherein a thickness of said mixed layer is at least equal to 3 nm.

11. The substrate as claimed in claim 1, wherein a thickness of said mixed layer is at most equal to 65 nm.

12. The substrate as claimed in claim 1, wherein said transparent electrically conductive layer composed of a doped oxide is joined to said mixed layer with interposition of a layer of the same undoped oxide.

13. The substrate as claimed in claim 12, wherein a combined thickness of the two layers of undoped oxide and of doped oxide is between 300 and 1600 nm, and a ratio of the thicknesses of the two layers is between 1:4 and 4:1.

14. A process for manufacturing a substrate as claimed in claim 1, comprising forming said layer of one or more first nitride(s) or oxynitride(s), or oxide(s) or oxycarbide(s), said mixed layer and said transparent electrically conductive layer by successive chemical vapor depositions.

15. The process as claimed in claim 14, wherein said depositions are carried out on a production line of the glass substrate.

16. A photovoltaic module comprising a substrate as claimed in claim 1.

17. A shaped electrically heated glass, comprising a substrate as claimed in claim 1.

18. A plasma screen comprising a substrate as claimed in claim 1.

19. A flat lamp electrode comprising a substrate as claimed claim 1.

20. A low-emissivity glass comprising a substrate as claimed in claim 1.

21. The substrate as claimed in claim 2, wherein said first and second nitride(s) or oxynitride(s), or oxide(s) or oxycarbide(s) are chosen from SiOC, SiO₂, SiON, TiO₂, TiN and Al₂O₃.

22. The substrate as claimed in claim 3, wherein said third nitride(s) or oxynitride(s), or oxide(s) or oxycarbide(s) are chosen from SnO₂, ZnO and InO.

23. The substrate as claimed in claim 4, wherein said transparent electrically conductive layer is composed of SnO₂:F, SnO₂:Sb, ZnO:Al, ZnO:Ga, InO:Sn, ZnO:B or ZnO:In.

24. The substrate as claimed in claim 7, wherein the [Si]/[Sn] molar ratio in said mixed layer is at least equal to 2.

25. The substrate as claimed in claim 11, wherein a thickness of said mixed layer is at most equal to 40 nm.

26. The substrate as claimed in claim 13, wherein the combined thickness of the two layers of undoped oxide and of doped oxide at most equal to 1100 nm.

27. The substrate as claimed in claim 26, wherein the combined thickness of the two layers of undoped oxide and of doped oxide at most equal to 900 nm.

28. A glass substrate bearing a transparent electrically conductive layer configured to form an electrode of a photovoltaic module, and including a doped oxide, and a layered structure arranged between the glass substrate and the transparent electrically conductive layer, the layered structure comprising a layer of a first nitride or oxynitride, or oxide or oxycarbide adapted to adhere to glass, and a mixed layer of a second nitride or oxynitride, or oxide or oxycarbide adapted to adhere to glass, and a third nitride or oxynitride, or oxide or oxycarbide capable of constituting, optionally in the doped state, a transparent electrically conductive layer.

29. A photovoltaic module comprising:
a glass substrate;
an electrode including a transparent electrically conductive layer that includes a doped oxide; and
a layered structure arranged between the glass substrate and the transparent electrically conductive layer, the layered structure comprising a layer of a first nitride or oxynitride, or oxide or oxycarbide adapted to adhere to glass, and a mixed layer of a second nitride or oxynitride, or oxide or oxycarbide adapted to adhere to glass, and a third nitride or oxynitride, or oxide or oxycarbide capable of constituting, optionally in the doped state, a transparent electrically conductive layer.
